(19) United States
(12) Patent Application Publication
(10) Pub. No.: US 2026/0093870 A1
(43) Pub. Date: Apr. 2, 2026

(54) SYSTEM AND METHOD FOR DEVELOPING VEHICLE DESIGN WITH ENGINEERING CONSTRAINTS

(71) Applicant: Toyota Research Institute, Inc., Los Altos, CA (US)

(72) Inventors: Hayata Morita, Cambridge, MA (US); Kohei Shintani, Cambridge, MA (US); Chenyang Yuan, Cambridge, MA (US); Frank Permenter, Newton, MA (US)

(73) Assignees: Toyota Research Institute, Inc., Los Altos, CA (US); Toyota Jidosha Kabushiki Kaisha, Toyota-shi Aichi-ken (JP)

(21) Appl. No.: 19/010,954

(22) Filed: Jan. 6, 2025

Related U.S. Application Data
(60) Provisional application No. 63/700,919, filed on Sep. 30, 2024.

(51) Int. Cl. G06F 30/27; G06F 30/15

(52) U.S. Cl. CPC G06F 30/27; G06F 30/15

(57) ABSTRACT

Systems, methods, and other embodiments described herein relate to generating vehicle design while satisfying engineering constraints. In one embodiment, a method includes generating a three-dimensional (3-D) model of a vehicle using a 3-D modeler, a target latent vector generated by a latent estimator that utilizes one or more target parameters, and outputting one or more vehicle performance parameters based on the 3-D model of the vehicle.

### CROSS-REFERENCE TO RELATED APPLICATION

This application claims priority to U.S. Provisional Patent Application No. 63/700,919, “VehicleSDF: A 3D generative model for constrained engineering design via surrogate modeling”, filed Sep. 30, 2024, the contents of both are hereby incorporated by reference in their entirety.

### TECHNICAL FIELD

The subject matter described herein relates, in general, to systems and methods for developing vehicle design while estimating and/or enforcing engineering constraints.

### BACKGROUND

Recent advances in generative Artificial Intelligence (AI) have opened new possibilities for addressing mechanical design problems while considering both mechanical performance and aesthetics at the same time. However, the integration of engineering constraints into the generative design process remains a significant challenge.

### SUMMARY

In one embodiment, a system for generating vehicle design while satisfying engineering constraints is disclosed. The system includes a processor and a memory in communication with the processor. The memory stores machine-readable instructions that, when executed by the processor, cause the processor to generate a three-dimensional (3-D) model of a vehicle using a 3-D modeler and a target latent vector generated by a latent estimator that utilizes one or more target parameters, and output one or more vehicle performance parameters based on the 3-D model of the vehicle.

In another embodiment, a method for generating vehicle design while satisfying engineering constraints is disclosed. The method includes generating a three-dimensional (3-D) model of a vehicle using a 3-D modeler and a target latent vector generated by a latent estimator that utilizes one or more target parameters, and outputting one or more vehicle performance parameters based on the 3-D model of the vehicle.

In another embodiment, a non-transitory computer-readable medium for generating vehicle design while satisfying engineering constraints is disclosed. The non-transitory computer-readable medium includes instructions that, when executed by a processor, cause the processor to generate a three-dimensional (3-D) model of a vehicle using a 3-D modeler and a target latent vector generated by a latent estimator that utilizes one or more target parameters, and output one or more vehicle performance parameters based on the 3-D model of the vehicle.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates vehicle geometric parameters.

FIG. 2 illustrates a method of training of a three-dimensional (3-D) modeler.

FIG. 3 illustrates training of a surrogate parameter estimator.

FIG. 4 illustrates one embodiment of a vehicle design system.

FIG. 5 illustrates a system controller.

FIG. 6 is a flowchart illustrating one embodiment of a method associated with vehicle design.

### DETAILED DESCRIPTION

Systems, methods, and other embodiments associated with systems and methods for vehicle design are disclosed. Utilizing Generative AI (Artificial Intelligence) tools for vehicle design may lead to significant inefficiency as the Generative AI tools are not capable of considering constraints when generating vehicle designs, and as such, may generate vehicle designs that do not meet, as an example, engineering constraints such as drag coefficient. This may lead to multiple vehicle design iterations that are repeatedly reviewed by designers and engineers before achieving a vehicle design that meets the desired constraints.

Current methods for generating vehicle design using Generative AI tools may not include breakthrough creativity as the Generative AI tools may generate designs based on a distribution of existing designs. Further and as previously mentioned, the Generative AI tools do not consider constraints when generating designs. Also, Generative AI tools are unable to consider specific machine-interpretable representations such as drag coefficients and/or vehicle weight distribution when generating a design.

In general, recent advances in Generative AI have attempted to address mechanical design issues while considering both mechanical performance and aesthetics at the same time. Deep generative models have demonstrated capabilities in producing complex shapes and designs that satisfy multiple objectives simultaneously. However, the integration of engineering constraints into the generative design process remains a significant challenge.

Accordingly, systems, methods, and other embodiments associated with vehicle design which satisfy engineering constraints are disclosed. The method includes a data-driven approach using a three-dimensional (3-D) vehicle data set to train a model that represents potential designs in a latent space that can be decoded into a three-dimensional (3-D) model. The method also includes training surrogate models to estimate engineering parameters from this latent space representation, thus enabling latent vectors to match specifications more efficiently. The system includes three key components, a 3-D model generator, a drag coefficient prediction model, and an image generator. The 3-D model generator further includes a latent estimator and a 3-D modeler. The latent estimator is trained to generate a latent vector based on geometric parameters related to engineering constraints. The 3-D modeler is trained to generate a 3-D model of a vehicle based on a latent vector. As such, the 3-D model generator is capable of generating 3-D vehicle shapes matching specified geometric parameters that come from engineering constraints. The method includes training the 3-D modeler on a 3-D vehicle dataset such as the ShapeNet dataset. The method further includes training the latent estimator based on the trained 3-D modeler and using a function fitting approach. The method may include training and using a surrogate model to determine vehicle performance based on the 3-D model of a vehicle. The method may further include training and using a model such as StableDiffusion with ControlNet to generate a stylized image of the vehicle based on the 3-D model of the vehicle. The stylized images may be photo-realistic images of the vehicle.

The embodiments disclosed herein present various advantages over conventional technologies that generate vehicle design. First, the embodiments are able to produce and fine-tune novel aesthetically pleasing designs that satisfy engineering constraints. Second, the embodiments may be utilized during the early stages of vehicle development, where multiple rapid iterations and evaluations are crucial. Third, the embodiments are capable of generating diverse 3-D vehicle shapes that meet specific mechanical constraints while also producing aesthetically pleasing designs, thus streamlining the design process and reducing the number of revisions. Fourth, the embodiments are capable of efficiently estimating engineering parameters from generated models without running expensive simulations.

Detailed embodiments are disclosed herein; however, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in the figures, but the embodiments are not limited to the illustrated structure or application.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details.

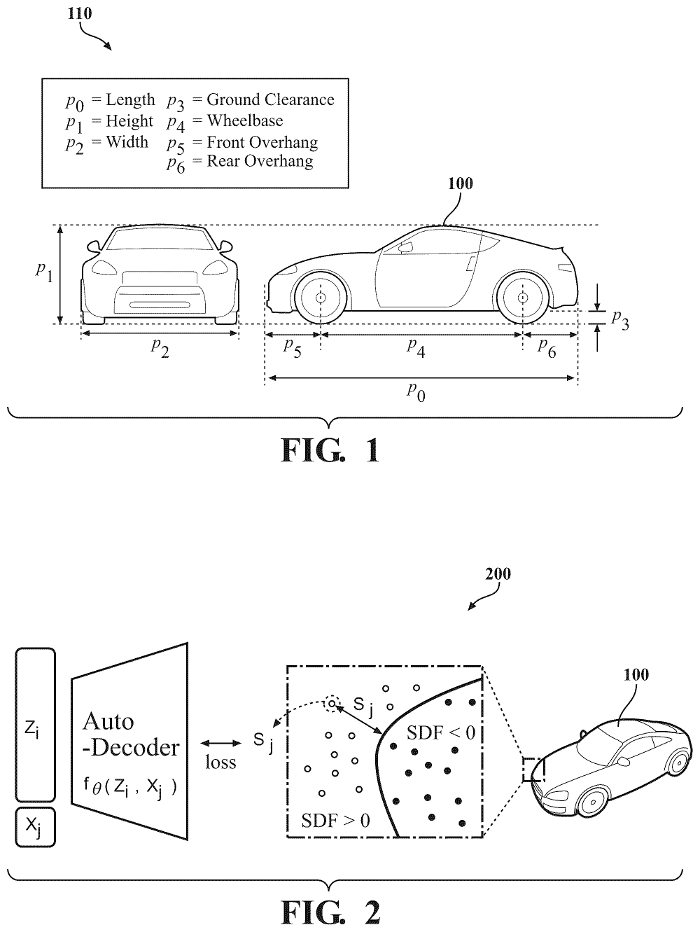

FIG. 1 illustrates vehicle geometric parameters 110. The vehicle geometric parameters 110 may include various dimensions of a vehicle 100 and may impact the performance of the vehicle 100. As an example, the vehicle geometric parameters 110 may affect vehicle performance parameters such as a drag coefficient. As shown in FIG. 1, the vehicle geometric parameters 110 may include vehicle length p₀, vehicle height p₁, vehicle width p₂, ground clearance p₃, wheelbase p₄, front overhang p₅, and/or rear overhang p₆.

FIG. 2 illustrates a method 200 of training of a three-dimensional (3-D) modeler. The 3-D modeler is capable of generating three-dimensional models of vehicles based on a latent vector. A latent vector is an intermediate representation of data, often used in deep learning. Latent vectors may be referred to as embedding vectors or representations. In this case, the latent vector is a representation of vehicle geometric parameters 110. As previously described, the vehicle geometric parameters 110 may include vehicle length p₀, vehicle height p₁, vehicle width p₂, ground clearance p₃, wheelbase p₄, front overhang p₅, and/or rear overhang p₆.

The 3-D modeler may be any suitable machine learning model. The 3-D modeler may be a generative model. Generative models are a class of machine learning models that can generate new data based on training data. As an example, the 3-D modeler may be a DeepSDF 3-D modeler, which utilizes a learned continuous Signed Distance Function (SDF) representation of a class of shapes that enables high quality shape representation, interpolation, and completion from partial and noisy 3-D input data. The method includes training the 3-D modeler on a 3-D vehicle data set. The 3-D vehicle data set includes 3-D vehicle data. The method includes training the 3-D modeler on the 3-D vehicle data to minimize a loss function that consists of a prediction error of the SDF values at each sample point, along with an L2 norm regularization term. As an example, the method utilizes a set of N shapes {Xᵢ}, where each shape Xᵢ is sampled at K points {xⱼ}∈R^{d}, and each point is assigned an SDF value {sⱼ}∈R. The SDF value {sⱼ} represents the signed distance from a surface, where points inside the surface have a negative sign, and points outside the surface have a positive sign. The relationship between these K sampled points and the SDF values is expressed as: Xᵢ:={(xⱼ,sⱼ):sⱼ=SDFⁱ (xⱼ)}. The 3-D modeler is trained by optimizing θ and z using the loss function:

$$arg {min}_{θ , {Z}_{i}} {\sum }_{i = 1}^{N} ( {\sum }_{j = 1}^{K} {ℒ}_{0} ( {f}_{θ} ( {z}_{i} , {x}_{j} ) , {s}_{j} ) + \frac{1}{{σ}_{L}^{2}} {‖ {z}_{i} ‖}_{2}^{2} )$$

The first term in the equation is the loss function [symbol] ₀ applied to the output of the model ƒ_{θ}(zⱼ,xⱼ)=sⱼ:R^{m}×R^{l}→R and the truth s), and the second term is given by the L₂-norm of the latent zᵢ and σ_{L}∈R as regularization. Given a set of spatial points xⱼ, a 3-D shape is generated by evaluating θ_{\hat{θ}}(\hat{z},xⱼ) and extracting the isosurface where SDF=0 using techniques such as ray casting, which is a technique that simulates how light interacts with objects in a virtual scene to create realistic lighting and images, or a marching cubes algorithm, which is a high resolution 3-D surface construction algorithm. Here, \hat{θ} and \hat{z} represent the optimized values of θ and z, respectively.

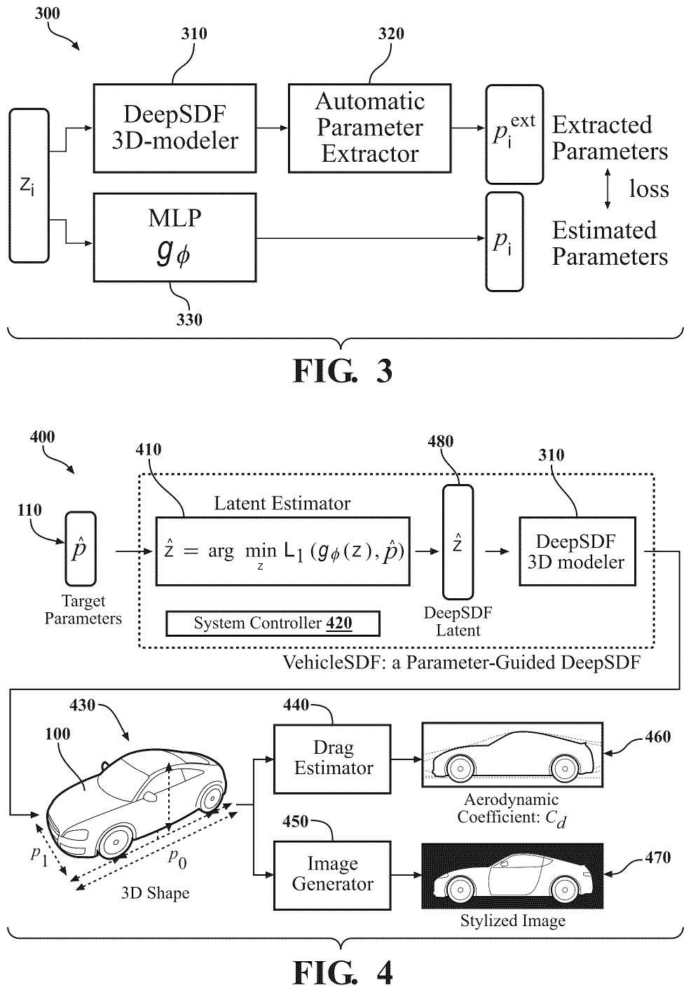

FIG. 3 illustrates a method 300 of training a latent estimator. As shown, the method 300 for training the latent estimator may include and utilize a 3-D modeler 310 such as a DeepSDF 3-D modeler, a parameter extractor 320, and a parameter estimator 330. The method 300 includes utilizing the parameter estimator 330 to optimize the latent vectors so as to ensure conformity with the target parameters. This parameter estimator 330 may be a multi-layer perceptron g_{Ø}(zᵢ)=pᵢ, where zᵢ∈R^{m} is the latent vector, pᵢ∈Rⁿ are the geometric parameters and Ø are the model's weights, optimized at train-time:

$$arg {min}_{∅} {\sum }_{i} {ℒ}_{1} ( {g}_{∅} ( {z}_{i} ) , {p}_{i}^{ext} )$$

where

$${p}_{i}^{ext}$$

are parameters extracted for each shape using any suitable extraction method and [symbol] ₁ is the mean-squared error. The method 300 includes fixing Ø and minimizing [symbol] ₁(g_{Ø}(\hat{z}),\hat{p}) to determine the latent vectors \hat{z} that match the target parameters \hat{p}.

More generally, the method 300 includes inputting each latent vector z; into the 3-D modeler 310 and the parameter estimator 330. The method 300 then includes the 3-D modeler 310 outputting a 3-D model of the vehicle 100 to the parameter extractor 320. The method 300 further includes the parameter extractor 320 mapping the 3-D model of the vehicle 100 within 3-D space using the x-, y-, and z axes. The parameter extractor 320 may then utilize any suitable image processing algorithm to identify the shape of the vehicle 100, the position of the wheels on the vehicle 100, as well as the geometric parameters of the vehicle 100 such as the vehicle length and the vehicle width.

The method 300 further includes training the parameter estimator 330 based on a relationship between zᵢ and pᵢ by fitting a function of zᵢ and pᵢ such that the loss (or the difference) between the parameters

$${p}_{i}^{ext}$$

being extracted by the parameter extractor 320 and the parameters pᵢ being outputted by parameter estimator 330 is at a minimum.

With reference to FIG. 4, one embodiment of the vehicle design system 400 is illustrated. The vehicle design system 400 outlines a pipeline for vehicle design and performance estimation. The vehicle design system 400 may include the latent estimator 410, the 3-D modeler 310, and a system controller 420. As an example, a user may input one or more geometric parameters \hat{p} 110 into the latent estimator 410. In response, the system controller 420 may activate the latent estimator 410, which has been trained as disclosed above, to receive the geometric parameters \hat{p} 110 and generate a latent vector \hat{z} 480 based on the geometric parameters \hat{p} 110. The system controller 420 may then activate the latent estimator 410 to output the latent vector z̅ 480 to the 3-D modeler 310. The system controller 420 may activate the 3-D modeler 310 to receive the latent vector \hat{z} 480 and generate a 3-D model 430 of a vehicle 100 based on the latent vector \hat{z} 480. The system controller 420 may activate the 3-D modeler 310 to output the 3-D model 430 of the vehicle 100 to one or more components capable of determining performance parameters such as a drag estimator 440 capable of determining aerodynamic coefficient C_{d} 460. Additionally and/or alternatively, the system controller 420 may activate the 3-D modeler 310 to output the 3-D model 430 of the vehicle 100 to an image generator 450 capable of generating a stylized image 470 of the vehicle 100.

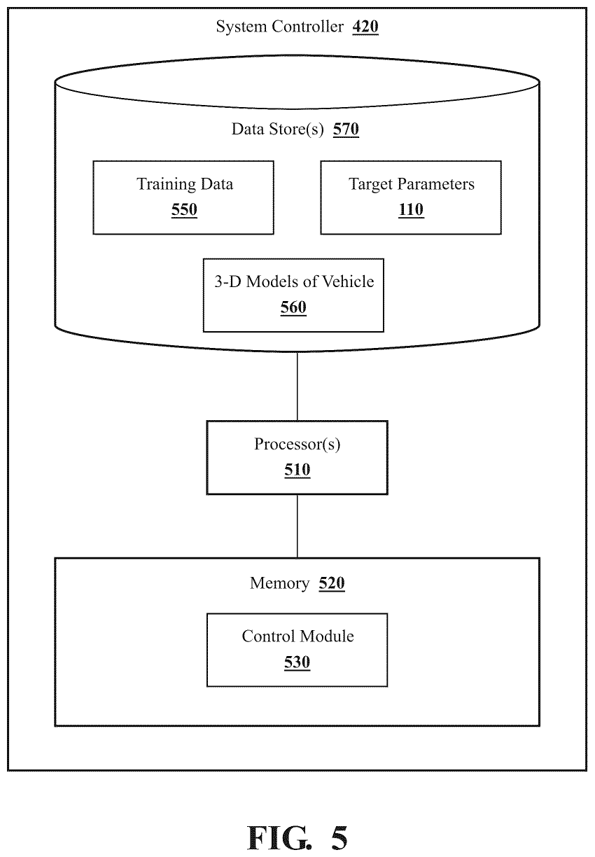

With reference to FIG. 5, one embodiment of the system controller 420 of FIG. 4 is further illustrated. The system controller 420 is shown as including a processor 510. Accordingly, the processor 510 may be a part of the system controller 420, or the system controller 420 may access the processor 510 through a data bus or another communication path. In one or more embodiments, the processor 510 is an application-specific integrated circuit (ASIC) that is configured to implement functions associated with a control module 530. In general, the processor 510 is an electronic processor, such as a microprocessor, which is capable of performing various functions as described herein.

In one embodiment, the system controller 420 includes a memory 520 that stores the control module 530 and/or other modules that may function in support of generating a 3-D model 430 of a vehicle 100. The memory 520 is a random-access memory (RAM), read-only memory (ROM), a hard disk drive, a flash memory, or another suitable memory for storing the control module 530. The control module 530 is, for example, machine-readable instructions that, when executed by the processor 510, cause the processor 510 to perform the various functions disclosed herein. In further arrangements, the control module 530 is a logic, integrated circuit, or another device for performing the noted functions that includes the instructions integrated therein.

Furthermore, in one embodiment, the system controller 420 includes a data store 570. The data store 570 is, in one arrangement, an electronic data structure stored in the memory 520 or another data store, and that is configured with routines that can be executed by the processor 510 for analyzing stored data, providing stored data, organizing stored data, and so on. Thus, in one embodiment, the data store 570 stores data used by the control module 530 in executing various functions.

For example, as depicted in FIG. 5, the data store 570 includes training data 540, target parameters 110, and 3-D models 430 of vehicles 100, along with, for example, other information that is used and/or produced by the control module 530. The training data 540 may include training data for latent estimator 410 and/or the 3-D modeler 310. The target parameters 110 are geometric parameters that may be entered by a user. The 3-D models 430 of vehicles 100 are the outputs of the 3-D modeler 310 based on a target latent vector ź 480.

While the system controller 420 is illustrated as including the various data elements, it should be appreciated that one or more of the illustrated data elements may not be included within the data store 570 in various implementations and may be included in a data store that is external to the system controller 420. In any case, the system controller 420 stores various data elements in the data store 570 to support functions of the control module 530.

In one embodiment, the control module 530 includes instructions that, when executed by the processor(s) 510, cause the processor(s) 510 to train a latent estimator 410. In one or more arrangements, the control module 530 can train the latent estimator 410 using the 3-D modeler 310 and a parameter extractor 320. The control module 530 can train the latent estimator 410 based on a set of latent vectors zᵢ and a set of parameters

$${p}_{i}^{ext}$$

extracted by the parameter extractor 320. In one or more arrangements, initially, the control module 530 may train the 3-D modeler 310 on a 3-D vehicle data set, as previously disclosed. The control module 530 may then train the latent estimator 410 by inputting a set of latent vectors zᵢ into the 3-D modeler 310 and a surrogate parameter estimator 330, which may be a multi-layer perceptron. As previously mentioned, the 3-D modeler 310 outputs a 3-D model 430 of a vehicle 100 in relation to each of the latent vectors zᵢ and the parameter extractor 320 extracts the geometric parameters

$${p}_{i}^{ext} .$$

The control module 530 determines a function for the surrogate parameter estimator 330 that minimizes the difference between the parameters pᵢ estimated by the surrogate parameter estimator and un parameters

$${p}_{i}^{ext}$$

extracted by the parameter extractor. The control module 530 then applies the function to the latent estimator 410.

In one embodiment, the control module 530 includes instructions that, when executed by the processor(s) 510, cause the processor(s) 510 to receive one or more target parameters 110. The target parameters 110 may include features of a vehicle 100 such as vehicle length p₀, vehicle height p₁, vehicle width p₂, ground clearance p₃, wheelbase p₄, front overhang p₅, and/or rear overhang p₆. The target parameters 110 may be entered by a human user or may be automatically generated and entered.

In one embodiment, the control module 530 includes instructions that, when executed by the processor(s) 510, cause the processor(s) 510 to generate a target latent vector \hat{z} 480 using the latent estimator 410 and based on the one or more target parameters \hat{p} 110. The control module 530 causes the latent estimator 410 to receive one or more of any combination of target parameters \hat{p} 110. The latent estimator 410 then operates on the received target parameters \hat{p} 110 based on the function that the latent estimator 410 has been trained on. The latent estimator 410 then outputs the target latent vector \hat{z} 480 based on the target parameter(s) \hat{p} and the function.

In one embodiment, the control module 530 includes instructions that, when executed by the processor(s) 510, cause the processor(s) 510 to generate a three-dimensional (3-D) model 430 of a vehicle 100 using the 3-D modeler 310 and based on the target latent vector \hat{z} 480. The control module 530 causes the 3-D modeler 310 to receive the target latent vector \hat{z} 480 from the latent estimator 410. The 3-D modeler 310 then operates on the target latent vector \hat{z} 480 to output the 3-D model 430 of the vehicle 100 based on the target latent vector \hat{z} 480. The 3-D modeler 310 may utilize any suitable algorithm to determine the 3-D model 430 of the vehicle 100 based on the target latent vector ź 480.

In one embodiment, the control module 530 includes instructions that, when executed by the processor(s) 510, cause the processor(s) 510 to output one or more vehicle performance parameters 460, 470 based on the 3-D model 430 of the vehicle 100. The control module 530 may activate the 3-D modeler 310 to output the 3-D model 430 to one or more vehicle performance determination model such as a drag estimator 440, a vehicle structural strength determination model, and/or vehicle weight distribution prediction model. The vehicle performance determination models are capable of determining one or more characteristics or features of a vehicle 100 based on a 3-D model 430 of the vehicle 100. The control module 530 may train the vehicle performance determination model(s) using any suitable algorithm. As an example, the control module 530 may train the drag estimator 440 to predict the drag coefficient value C_{d} 460 of the vehicle 100 based on a 3-D model 430 of the vehicle 100. As such, in response to receiving a 3-D model 430 of the vehicle 100, the drag estimator 440 may predict the associated drag coefficient value C_{d} 460.

In one embodiment, the control module 530 includes instructions that, when executed by the processor(s) 510, cause the processor(s) 510 to generate a stylized image 470 of the vehicle 100 using an image generator 450 and based on the 3-D model 430 of the vehicle 100. In such arrangements, the image generator 450 may be trained on generating stylized images of a vehicle based on 3-D models of vehicles. As such, the image generator 450 may receive a 3-D model 430 of the vehicle 100 from the 3-D modeler 310 and then, output one or more stylized images 470 of the vehicle 100.

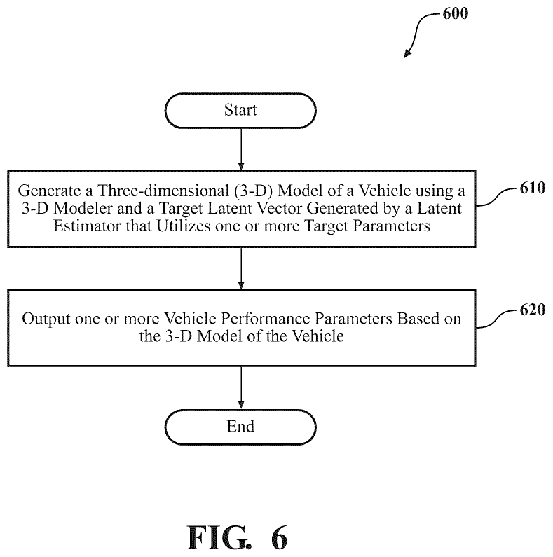

FIG. 6 is a flowchart illustrating one embodiment of a method 600 associated with vehicle design. The method 600 will be described from the viewpoint of the system controller 420 of FIGS. 4-5. However, the method 600 may be adapted to be executed in any one of several different situations and not necessarily by the system controller 420 of FIGS. 4-5.

At step 610, the control module 530 may cause the processor(s) 510 to generate a three-dimensional (3-D) model 430 of a vehicle 100 using a 3-D modeler 310 and a target latent vector \hat{z} 480 generated by a latent estimator 410 that utilizes one or more target parameters 110. The control module 530 may cause the processor(s) 510 to train a latent estimator 410. The control module 530 may first train a 3-D modeler 310 and then train the latent estimator 410 based on the 3-D modeler 310 and a parameter extractor 320 as disclosed above. The control module 530 may cause the processor(s) 510 to receive one or more target parameters 110. The control module 530 may feed the target parameters 110 to the latent estimator 410. The control module 530 may cause the processor(s) 510 to generate a target latent vector \hat{z} 480 using the latent estimator 410 and based on the one or more target parameters 110. The latent estimator 410 may utilize a function such as disclosed above to generate the latent vector \hat{z} 480. The control module 530 may activate the 3-D modeler 310 to receive the target latent vector \hat{z} 480 and generate a 3-D model 430 of the vehicle 100 based on the target latent vector \hat{z} 480.

At step 620, the control module 530 may cause the processor(s) 510 to output one or more vehicle performance parameters 460, 470 based on the 3-D model 430 of the vehicle 100. As previously described, the control module 530 may activate the 3-D modeler 310 to output a model 430 of the vehicle 100 to one or more vehicle performance determination models. The vehicle performance determination model such as the drag estimator 440 may determine the drag coefficient value C_{d} 460 of the vehicle 100 based on the 3-D model 430 of the vehicle 100.

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-6, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain or store a program for use by or in connection with an instruction execution system, apparatus, or device.

Generally, modules, as used herein, include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A system comprising:
a processor; and
a memory storing machine-readable instructions that, when executed by the processor, cause the processor to:
generate a three-dimensional (3-D) model of a vehicle using a 3-D modeler and a target latent vector generated by a latent estimator that utilizes one or more target parameters; and
output one or more vehicle performance parameters based on the 3-D model of the vehicle.

2. The system of claim 1, wherein the one or more vehicle performance parameters include a drag coefficient value and wherein the machine-readable instructions further include instructions that when executed by the processor cause the processor to:
train a drag coefficient prediction model; and
generate the drag coefficient value using the drag coefficient prediction model and the 3-D model of the vehicle.

3. The system of claim 1, wherein the machine-readable instructions further include instructions that when executed by the processor cause the processor to:
generate a stylized image of the vehicle using an image generator and the 3-D model of the vehicle.

4. The system of claim 1, wherein the one or more target parameters include at least one of:
vehicle length;
vehicle height;
vehicle width;
ground clearance;
wheelbase;
front overhang; and
rear overhang.

5. The system of claim 1, wherein the machine-readable instructions further include instructions that when executed by the processor cause the processor to:
train the 3-D modeler on a 3-D vehicle data set.

6. The system of claim 1, wherein the machine-readable instructions further include instructions that when executed by the processor cause the processor to:
train the latent estimator using the 3-D modeler, a parameter extractor, a set of latent vectors, and a set of parameters extracted by the parameter extractor.

7. The system of claim 1, wherein the machine-readable instructions further include instructions that when executed by the processor cause the processor to:
train the latent estimator using a multi-layer perceptron.

8. A method comprising:
generating a three-dimensional (3-D) model of a vehicle using a 3-D modeler and a target latent vector generated by a latent estimator that utilizes one or more target parameters; and
outputting one or more vehicle performance parameters based on the 3-D model of the vehicle.

9. The method of claim 8, wherein the one or more vehicle performance parameters include a drag coefficient value and further comprising:
training a drag coefficient prediction model; and
generating the drag coefficient value using the drag coefficient prediction model and the 3-D model of the vehicle.

10. The method of claim 8, further comprising:
generating a stylized image of the vehicle using an image generator and the 3-D model of the vehicle.

11. The method of claim 8, wherein the one or more target parameters include at least one of:
vehicle length;
vehicle height;
vehicle width;
ground clearance;
wheelbase;
front overhang; and
rear overhang.

12. The method of claim 8, further comprising:
training the 3-D modeler on a 3-D vehicle data set.

13. The method of claim 8, further comprising:
training the latent estimator using the 3-D modeler and a parameter extractor and a set of latent vectors and a set of parameters extracted by the parameter extractor.

14. The method of claim 8, further comprising:
training the latent estimator using a multi-layer perceptron.

15. A non-transitory computer-readable medium including instructions that when executed by a processor cause the processor to:
generate a three-dimensional (3-D) model of a vehicle using a 3-D modeler and a target latent vector generated by a latent estimator that utilizes one or more target parameters; and
output one or more vehicle performance parameters based on the 3-D model of the vehicle.

16. The non-transitory computer-readable medium of claim 15, wherein the one or more vehicle performance parameters include a drag coefficient value and wherein the instructions further include instructions that when executed by the processor cause the processor to:
train a drag coefficient prediction model; and
generate the drag coefficient value using the drag coefficient prediction model and the 3-D model of the vehicle.

17. The non-transitory computer-readable medium of claim 15, wherein the instructions further include instructions that when executed by the processor cause the processor to:
generate a stylized image of the vehicle using an image generator and the 3-D model of the vehicle.

18. The non-transitory computer-readable medium of claim 15, wherein the one or more target parameters include at least one of:
vehicle length;
vehicle height;
vehicle width;
ground clearance;
wheelbase;
front overhang; and
rear overhang.

19. The non-transitory computer-readable medium of claim 15, wherein the instructions further include instructions that when executed by the processor cause the processor to:
train the 3-D modeler on a 3-D vehicle data set.

20. The non-transitory computer-readable medium of claim 15, wherein the instructions further include instructions that when executed by the processor cause the processor to:
train the latent estimator using the 3-D modeler and a parameter extractor and a set of latent vectors and a set of parameters extracted by the parameter extractor.
